(19) United States
(12) Patent Application Publication
(10) Pub. No.: US 2018/0047589 A1
(43) Pub. Date: Feb. 15, 2018

(54) LEAD CARRIER WITH PRINT FORMED PACKAGE COMPONENTS AND CONDUCTIVE PATH REDISTRIBUTION STRUCTURES

(71) Applicants: Philip E ROGREN, San Jose, CA (US); EOPLEX LIMITED, New Territories Hong Kong (CN)

(72) Inventor: Philip E ROGREN, San Jose, CA (US)

(73) Assignee: EOPLEX LIMITED, Hong Kong (CN)

(21) Appl. No.: 15/542,075

(22) PCT Filed: May 4, 2016
(86) PCT No.: PCT/US2016/030767

§ 371 Date: Jul. 7, 2017

Related U.S. Application Data
(60) Provisional application No. 62/156,488, filed on May 4, 2015.

(51) Int. Cl. H01L 21/48; H01L 23/495; H01L 23/498; H01L 21/56

(52) U.S. Cl. CPC H01L 21/4832; H01L 21/568; H01L 23/49541; H01L 23/49872; H01L 23/49861; H01L 23/49548; H01L 2224/48247; H01L 2224/85207; H01L 2224/45139; H01L 2224/45147; H01L 2224/45144; H01L 2924/18301

(57) ABSTRACT

A lead carrier includes a temporary support layer, member, medium, or carrier upon which are dispersed a plurality of package sites, organized in a predetermined pattern such as a matrix or array. Each package site within a continuous sheet of mold compound of the lead carrier includes a semiconductor die; a set of terminal structures, each having a top side and an opposing back side that is exposed at a back side of the continuous sheet of mold compound; and a set of electrical current path redistribution structures, each formed as an elongate wiring structure having a first end, a second end distinct from the first end, a top surface, an opposing bottom surface, a width, and a thickness between its top and bottom surfaces. Each redistribution structure as-fabricated is either electrically pre-coupled to a predetermined terminal structure, or electrically isolated from each terminal structure.

### TECHNICAL FIELD

Aspects of the present disclosure relate generally to lead carriers on which packaged semiconductor die can be fabricated at package sites. More particularly, aspects of the present disclosure relate to lead carriers in which package sites include sintered package components formed on and which have surface mount solder joint interfaces that reside on a temporary support layer, member, medium, or carrier that can be peeled away from the package sites after a molding process. Package sites can include conductive path redistribution structures therein, which are vertically separated or offset from the surface mount interfaces of the sintered package components.

### BACKGROUND

The demand for smaller and more capable portable electronic systems, combined with the increased level of integration in today's semiconductor devices, is driving a need for smaller semiconductor packages with greater numbers of input/output terminals. At the same time, there is relentless pressure to reduce the cost of all components in consumer electronic systems, including semiconductor packages. The Quad Flat No lead (QFN) semiconductor package family is among the smallest and most cost effective of all semiconductor package types, but when fabricated with conventional techniques and materials has significant limitations with respect to the number of I/O terminals and the electrical performance that the technology can support.

QFN packages are conventionally assembled on an area array lead frame. The lead frame provides the parts of the QFN package that facilitate fixing a semiconductor die or integrated circuit chips within the package, such that top surfaces of I/O terminals or pads in the QFN package can be connected to the semiconductor die through wire bonds. In a finished QFN package, back surfaces of these I/O terminals serve as solder joints that facilitate establishing electrical couplings between the packaged semiconductor die and an electronic system board by way of a conventional surface mount soldering technique, in a manner readily understood by individuals having ordinary skill in the relevant art.

FIG. 1 illustrates a conventional etched area array lead frame 10, which is formed of a thin copper sheet that is photolithographically patterned and etched to provide an array of package sites 20 distributed across the lead frame 10. A lead frame 10 can contain tens to thousands of package sites 20. FIG. 2 is a magnified view showing an individual package site 20. Each package site 20 includes a die attach pad or die paddle 40, and an array of I/O terminals or wire bond pads 30 disposed around the die paddle 40. More particularly, the I/O terminals 30 are disposed around the die paddle 40 in such a way as to allow for the formation of wire bonds between the top surfaces of the I/O terminals 30 and a semiconductor die fixed to the top surface of the die paddle 40. The I/O terminals 30 and the die paddle 40 are provided with a surface coating that is compatible with gold thermosonic wire bonding. The back sides of the I/O terminals 30 and the die paddle 40 are provided with a surface coating that is compatible with surface mount soldering techniques. The die paddle 40 and the I/O terminals 30 are each held in position by one or more tie bars 50 that electrically connect the die paddle 40 and the I/O terminals 30 to shorting structures or bars 55 that surround the package site 20, and which are physically and electrically connected to the rest of the lead frame 10. Because the shorting bars 55 electrically connect every I/O terminal 30 and die paddle 40 in every package site 20 to the lead frame 10, they must be severed completely to form each finished QFN package.

More particularly, the tie bars 50 must be designed such that they can all be disconnected from the shorting bars 55 during singulation or isolation of the individual packaged semiconductor dies from the lead frame 10, leaving the die attach paddle 40 and I/O terminals 30 of each packaged semiconductor die electrically isolated from the lead frame 10 and each other packaged semiconductor die. Typically, the tie bars 50 are connected to the shorting bars 55 surrounding each package site 20 just outside of the footprint of the final QFN package. The shorting bars 55 are sawn away during the singulation process, leaving the tie bars 50 exposed at the edges of the final QFN package.

The requirement that all of the package components be connected to the lead frame 10 by metal structures, i.e., the tie bars 50, severely limits the number of leads that can be implemented in any given package outline. For any wire bond pads 30 inside an outermost row of wire bond pads 30, the tie bars 50 must be routed between the wire bond pads 30 of the outermost row of wire bond pads 30. The minimum scale of these tie bars 50 is such that only one tie bar 50 can be routed between two adjacent wire bond pads 30, and thus only two rows of wire bond pads 30 may be implemented in a standard QFN lead frame 10. Because of the present relationship between die size and lead count, standard QFN packages are limited to around 100 I/O terminals or wire bond pads 30, with the majority of packages having no more than about 60 I/O terminals or wire bond pads 30. This limitation rules out the use of QFN packages for many types of semiconductor devices that would otherwise benefit from the smaller size and lower cost of QFN technology.

After integrated circuit chips are mounted to the lead frame 10 and attached and connected to the wire bond pads 30 by wire bonds, the lead frame 10 is completely encapsulated with epoxy mold compound in a transfer molding process. Because the lead frame 10 is largely open front to back, a layer of high temperature tape is applied to the back side of the lead frame 10 prior to the wire bonding and molding processes, thereby defining the back plane of the lead frame 10 and the QFN packages that are fabricated thereon. Because this tape must withstand high temperature wire bonding and molding processes without adverse effect, the tape is relatively expensive. The process of applying, removing the tape, and removing adhesive residues can add upward of $1.00 to the cost of processing each lead frame 10.

The most common singulation technique for separating the individual QFN packages from the lead frame 10 is sawing. Because a saw must cut through the epoxy mold compound and must also remove all of the shorting bars 55 just outside each package outline, the sawing process is slower and saw blade life considerably shorter than if only mold compound needed to be cut.

Moreover, the fact that the shorting bars 55 are removed during the singulation process means that the semiconductor die within each QFN package cannot the tested until after singulation is complete. Handling thousands of tiny QFN packages, and assuring that each is presented to a testing system in the correct orientation is much more expensive than being able to test the packages present on an entire lead frame with each package in a known location.

A process known as punch singulation addresses the package testing problems associated with saw singulation, and allows testing of QFN packages while they reside in the lead frame, but substantially increases cost by cutting utilization of the lead frame to less than 50% of that of a saw singulated lead frame. Punch singulation also imposes a requirement for dedicated mold tooling for every basic lead frame design. Standard lead frames 10 designed for saw singulation use a single mold cap for all lead frames of the same dimensions.

In both saw singulated and punch singulated QFN packages, the tie bars 50 remain in the completed package, and represent capacitive and inductive parasitic elements that cannot be removed. These now superfluous pieces of metal can significantly adversely impact the performance of the packaged semiconductor die, precluding the use of QFN packages for many high performance die.

Several concepts have been advanced for producing QFN type packages that eliminate the limitations of etched lead frames 10. Among those is a process described in U.S. Pat. No. 8,525,305, incorporated herein by reference in its entirety, which provides an array of package components disposed at predetermined locations on a temporary carrier. These package components are deposited at predetermined locations on the temporary carrier as a metallic paste formed of a metal powder that is distributed or dispersed within a temporary medium or vehicle. The metallic paste is raised to a sintering temperature to remove the temporary vehicle and sinter the metal powder therein to a high density on the temporary carrier. As a result of such sintering, the sintered metal resides on the temporary carrier in the form of package components.

While this process eliminates the tie bars 50 of the etched lead frame 10, for any given package component it can produce only package component structures that have substantially the same shape on each of (a) the package component surface in contact with the temporary carrier, i.e., the back surface or surface mount interface of the package component, and (b) the opposite surface of the package component, i.e., the top or wire bonding surface of the package component. Consequently, wire bonding to the top surface of any given package component must be performed at substantially the same (x, y) location or coordinates as surface mount soldering to the back surface of the package component.

In many semiconductor packaging situations, it is desirable to relocate a wire bond to an (x, y) location that is significantly separated or distant from the location of its typical corresponding surface mount interface to allow, for instance, for shorter wire bonds, or wire bond electrical connection to surface mount interfaces located under the area where the die is positioned, or the selective creation of conductive paths between two structures or devices in a single package. Thus, it is desirable to provide a lead frame manufacturing process that enables conductive path redistribution within the packages fabricated on the lead frame, such that particular conductive paths within a package can be redistributed or re-routed to customized (x, y) locations within the package.

One approach to providing such conductive path redistribution capability is a modification of the etched lead frame process, wherein a front side pattern is etched to about half the thickness of the lead frame, and the backside of the lead frame is left intact until after the wire bonding and molding processes are complete. Once molding is complete, a backside pattern is printed that corresponds to the pattern of wire bonds established during the wire bonding process, and the lead frame is further etched to remove all of the metal except for the backside portion of the wire bond pads and die paddles surrounded thereby. This double etch process provides redistribution capability by allowing for a first patterned level of metallization with design freedom within the resolution capabilities of the etching process, and eliminates all of the issues associated with connective metal structures within the package. However, the cost of the double etched lead frame is substantially more than the cost of standard etched lead frames, and the etching and plating processes are environmentally undesirable.

### SUMMARY

A lead carrier in accordance with embodiments of the present disclosure includes a temporary support layer, member, medium, or carrier upon which are dispersed a plurality of package sites (e.g., organized in a predetermined pattern such as a matrix or array) at which semiconductor die packages (hereafter packages for purpose of brevity) can be fabricated, assembled, or manufactured. Each package site includes: at least one die fixing structure, element, or interface for placing, positioning, and/or fixing at least one semiconductor die thereto; and at least one terminal structure, element, or pad arrayed in proximity to the die fixing structure. Depending upon embodiment details, each package site includes one or more terminal structures, for instance, certain embodiments can include one terminal structure, whereas other embodiments can include up to hundreds of terminal structures, associated with the die fixing structure thereof. Each terminal structure includes a highly conductive metal that is compatible with conventional processes for, gold, copper or silver thermo-sonic wire bonding and surface mount technology (SMT) soldering.

For each package site, the die fixing structure can be formed of the same material as the terminal structures associated therewith, and can be analogous to, correspond to, or exist in the general form or form of a die attach pad; or alternatively, the die fixing structure can constitute a predetermined region or spatial area on the temporary support layer associated with the terminal structure(s) that surround the die fixing structure. The die fixing structure is designed to receive a semiconductor die during the package fabrication, assembly, or manufacture process.

In embodiments in which the terminal structures and the die fixing structures are formed or composed the same material(s), they can be deposited (simultaneously or serially) in a predetermined pattern on the temporary support layer in the form of a suspension that includes at least one metal powder and a suspension medium, which are then heated to a sufficiently high temperature to decompose and disperse the suspension medium and cause the metal powder to sinter into a high density electrically conductive mass. After sintering, the sintered metal structure that remain on the temporary support layer, and which form the die fixing structures and terminal structures associated therewith, retain or exhibit shapes having a predictable correspondence with or approximation of the shapes taken by the suspension that was deposited on the temporary support layer.

The adhesion of the sintered metal to the temporary support layer is carefully controlled to provide (a) adequate or sufficiently high adhesion to prevent damage or detachment of the sintered metal from the temporary support layer during the package assembly process; and additionally (b) sufficiently low adhesion to allow the temporary support layer to be peeled away after the package sites are assembled with semiconductor die and wire bonds and are encapsulated with epoxy mold compound, leaving all of the die fixing structures and terminal structures undamaged and embedded in the epoxy mold compound.

Further to the foregoing, embodiments in accordance with the present disclosure provide a lead carrier in which each package site thereof at which packages are assembled includes an array of package components resident on or temporarily fixed to the temporary support layer, wherein a different configuration of package components can optionally, selectively, or customizably exist on a surface mount interface or back or bottom surface of any given package site or package relative to a configuration of package components at a wire bonding surface or closest to a top surface of the package site or package.

Such an option is provided by way of the inclusion of a set of (i.e., one or more) electrical current path redistribution path structures at a package site, or correspondingly, within the package fabricated thereat. The set of electrical current path redistribution path structures can include one or more types of electrical current path redistribution structures therein. More particularly, depending upon embodiment details, such redistribution structures can include pre-linked redistribution structures, and/or initially-unlinked redistribution structures. Each type of redistribution structure includes or forms an electrically conductive elongate wiring structure, element, or member (e.g., an elongate interconnect structure) that is typically formed of the same material as the terminal structures, and which is routed along, beside, between, and/or around one or more terminal structures. A designation of “pre-linked” or “initially unlinked” respectively indicates whether an as-fabricated redistribution structure under consideration is (a) electrically pre-coupled or pre-connected to a corresponding predetermined terminal structure, or (b) initially electrically floating or isolated relative to terminal structures as a result of a manner in which redistribution structures and terminal structures are formed during a lead carrier manufacturing process.

Each pre-linked redistribution structure corresponds to and has a first or proximal end portion or end that is electrically pre-coupled or pre-connected to a particular terminal structure as a result of a manner in which the pre-linked redistribution structure and its corresponding terminal structure are formed or joined together during the lead carrier manufacturing process. A pre-linked redistribution structure extends away from its corresponding terminal structure such that a second or distal end portion or end of the pre-linked redistribution structure is disposed or resides at a selected, customized, or target destination or (x, y) location within the package site or package, which relative to the overall dimensions of the package site or package can be or typically is significantly away or remote from the terminal structure to which the redistribution structure corresponds. Thus, each pre-linked redistribution structure includes or forms an elongate wiring structure that extends between or from the pre-linked redistribution structure's first and second ends, where the first end is electrically pre-coupled or pre-connected to a predetermined terminal structure corresponding to the pre-linked redistribution structure (e.g., by way of being physically joined to this terminal structure as-fabricated). The second end is selectively couplable to a particular input/output junction or wire bond pad of the semiconductor die by way of wire bonding, in a manner readily understood by individuals having ordinary skill in the relevant art.

Each initially-unlinked redistribution structure includes or forms an elongate wiring structure having a first end portion or end and a second end portion or end that define the extremities of the initially-unlinked redistribution structure. The first end of an initially-unlinked redistribution structure is positioned or disposed at a particular or predetermined first (x, y) location within the package site or package; and the second end of the initially-unlinked redistribution structure is positioned or disposed at a particular or predetermined second (x, y) location within the package site or package, which is distinct from and can be remote from the first (x, y) location relative to the overall dimensions of the package site or package, respectively. Any given initially-unlinked redistribution structure is not pre-linked, pre-coupled, or pre-connected to a corresponding terminal structure of the package site or package as a result of the formation of initially-unlinked redistribution structures and terminal structures during the lead carrier fabrication process. Subsequent to the formation of the initially-unlinked redistribution structures and terminal structures, a portion of a given initially-unlinked redistribution structure, such as the first end or second end thereof or a particular segment of the initially-unlinked redistribution structure's length, can be selectively or selectably coupled to a particular terminal structure within the package site or package by way of wire bonding; and another portion of the initially-unlinked redistribution structure can be selectively or selectably coupled to a particular wire bond pad of the semiconductor die by way of wire bonding.

As indicated above, for any given terminal structure of a package site or package, the surface mount interface of the terminal structure is exposed at or defines a back or bottom surface of the package site or package, respectively. A given pre-linked or initially-unlinked redistribution structure includes a top surface or upper side that is parallel to or coplanar with one or more terminal structures (e.g., each terminal structure in some embodiments). For instance, a pre-linked redistribution structure has a top surface that is parallel to and which connects to its corresponding terminal structure at a peripheral portion of this terminal structure, at the surface of the terminal structure furthest from the surface of the temporary support layer (i.e., the top surface of the terminal structure).

A given pre-linked or initially-unlinked redistribution structure also includes a parallel bottom surface or underside situated at or above a predetermined height or point (e.g., an approximate mid-point) along the vertical extent, height, depth, or thickness of one or more terminal structures (e.g., each terminal structure), above (not in direct contact with) the terminal structures' surface mount interfaces and above (not in direct contact with) the temporary support layer. Thus, the redistribution structures have a thickness that is less than the thickness of the terminal structures, and the bottom surface or underside of the redistribution structures are vertically offset or separated away from the surface mount interfaces or back sides of the terminal structures (and correspondingly, the back side of the package site or package).

In accordance with multiple embodiments of the present disclosure, a layer of electrically insulating supportive or supporting material (e.g., an electrically insulating material having a predetermined dielectric constant or predetermined dielectric constant behaviour across one or more electrical signal frequency and/or temperature ranges) can optionally be disposed or dispersed on the surface of the temporary support layer, at least partially or completely filling the thickness between the temporary support layer and the bottom surfaces of the redistribution structures. In certain embodiments, the electrically insulating layer has a thickness that is greater than the thickness of the space between the bottom of the redistribution structures and the temporary support layer, resulting in a portion of the thickness of the redistribution structures being embedded in, and supported by the electrically insulating layer.

In an embodiment, the electrically insulating layer includes or is formed of a granular structure or material having, e.g., between 25% and 90% void space. The granular structure is selected or chosen, with respect to particle size and morphology of the granules thereof, to allow resin from the mold compound to infiltrate the granular structure during a molding process or operation, thus reinforcing the electrical insulating layer.

Particular non-limiting objectives and/or advantages of one or more embodiments in accordance with the present disclosure include at least some of the following:
(a) providing electrical interconnect components of a semiconductor package that allows for the implementation of a simplified QFN package assembly process to produce QFN packaged semiconductor dies at lower cost than by using prior art techniques, and which ideally eliminates steps from a standard QFN package assembly process;
(b) providing the electrical interconnect components of a semiconductor package arrayed on a sacrificial or temporary support layer, member, medium, or carrier that can be peeled away after a molding process to yield a continuous strip of packaged semiconductor dies with no electrical connection between any two packaged semiconductor dies;
(c) providing the electrical interconnect components of a semiconductor package that enables higher electrical performance because only a minimum amount of metal is incorporated into the package to facilitate electrical connection of the packaged semiconductor die to a system board of an electronic system;
(d) providing the electrical interconnect components of a semiconductor package that allows for the inclusion of more than two rows of I/O terminals and many times the number of I/O terminals that are practical with conventional lead frame based QFN packages;
(e) providing the electrical interconnect components of a semiconductor package that allows much greater design flexibility to incorporate features such as multiple power and ground structures and multiple die attach pads than conventional lead frame based QFN packages;
(f) providing a secondary interconnect layer with finer or fine geometric features to allow for routing one or more interconnect structures between adjacent surface mount solder pads of a semiconductor package; and
(g) providing a secondary interconnect layer that is not exposed to the bottom or back surface of the molded package.

Additional and/or other objectives and advantages of certain embodiments in accordance with the present disclosure will become apparent from consideration of the representative embodiments detailed in the description below and the drawings corresponding thereto.

In accordance with an aspect of the present disclosure, a lead carrier for assembling packaged semiconductor die encapsulated in a mold compound includes a continuous sheet of mold compound having a top side and an opposing back side, the continuous sheet of mold compound forming an array of package sites, each package site corresponding to a semiconductor die package, each package site including: a semiconductor die having a top side and an opposing back side, and which includes at least one wire bond pad on its top side; a set of terminal structures, each terminal structure formed of a sintered material and having a top side, an opposing back side that is exposed at the back side of the continuous sheet of mold compound, and a height between its top and back sides; a set of electrical current path redistribution structures, each redistribution structure comprising an elongate wiring structure formed of the sintered material and having a first end, a second end distinct from the first end, a top surface, an opposing bottom surface, a width, and a thickness between its top and bottom surfaces, wherein within the set of redistribution structures any given redistribution structure as-fabricated is either (a) a pre-linked redistribution structure that is electrically pre-coupled to a predetermined terminal structure, or (b) an initially-unlinked redistribution structure that is electrically isolated from each terminal structure; a dielectric structure disposed between the bottom surface of each redistribution structure and the back side of the continuous sheet of mold compound; a plurality of wire bonds that selectively establishes electrical couplings between the semiconductor die, the set of terminal structures, and the set of redistribution structures; and hardened mold compound that encapsulates the semiconductor die, the set of terminal structures, the set of redistribution structures, and the plurality of wire bonds, wherein the bottom surface of each redistribution structure is offset away from the back side toward the top side of the continuous sheet of mold compound.

Each redistribution structure is routed along, between, and/or around peripheral portions of one or more terminal structures. Each package site can include up to hundreds of terminal structures, and each package site can include a plurality of redistribution structures routed between peripheral portions of terminal structures.

At least one redistribution structure can integrally include a remote terminal structure having has a width that is greater than the width of the elongate wiring structure, and can possibly integrally include a plurality of remote terminal structures.

At each package site, the top surface of each redistribution structure is parallel with the top side of each terminal structure. The bottom surface of each redistribution structure is not exposed at the back side of the continuous sheet of mold material. Also, the back side of each terminal structure defines a surface mount junction for the semiconductor die package corresponding to the package site.

The plurality of wire bonds includes first wire bonds selectively formed between the semiconductor die and the set of redistribution structures, and second wire bonds selectively formed between the semiconductor die and the set of terminal structures. The set of redistribution structures can include at least one initially-unlinked redistribution structure, and the plurality of wire bonds can include third wire bonds selectively formed between the set of terminal structures and the at least one initially-unlinked redistribution structure. The set of redistribution structures can include at least one pre-linked redistribution structure and at least one initially-unlinked redistribution structure.

The dielectric structure includes or is formed of a granular material having void spaces therein occupied by the mold compound. The granular material can include between 25%-90% void spaces therein prior to mold compound occupancy of the void spaces.

At each package site, the dielectric structure vertically extends from the bottom of the package site up to a fraction of the thickness of each redistribution structure, below the top surface of each redistribution structure.

During fabrication, the lead carrier includes a temporary support layer having a top side that supports the bottom side of the continuous planar sheet of mold compound and the bottom side of each terminal structure, and which is peelably removable therefrom. Each terminal structure has a peripheral border, and the peripheral border of at least one terminal structure within the set of terminal structures includes an overhang region that causes an upper portion of the terminal structure to laterally extend beyond a lower portion of the terminal structure, and wherein the overhang region interlocks with the hardened mold compound to resist downward vertical displacement of the terminal structure from the hardened mold compound. At each package site a level of adhesion of each terminal structure to the top surface of the temporary support layer is less than a level of adhesion of the peripheral border of the terminal structure to the hardened mold compound.

Each package site includes a die fixing structure having a top side on which the back side of the semiconductor die resides, and a back side that is exposed at the back side of the continuous sheet of mold compound to define a surface mount junction of the package corresponding to the package site.

In accordance with an aspect of the present disclosure, a semiconductor die package having a top side and an opposing back side includes: a semiconductor die having a top side and an opposing back side, and which includes at least one wire bond pad on its top side; a set of terminal structures, each terminal structure formed of a sintered material and having a top side, an opposing back side that is exposed at the back side of the continuous sheet of mold compound, and a height between its top and back sides; a set of electrical current path redistribution structures, each redistribution structure comprising an elongate wiring structure formed of the sintered material and having a first end, a second end distinct from the first end, a top surface, an opposing bottom surface, and a thickness between its top and bottom surfaces, wherein within the set of redistribution structures, any given redistribution structure as-fabricated is either (a) a pre-linked redistribution structure that is electrically pre-coupled to a predetermined terminal structure, or (b) an initially-unlinked redistribution structure that is electrically isolated from each terminal structure; a dielectric structure that occupies a lower portion of the package between the bottom surface of each of the at least one redistribution structures and the bottom of the continuous sheet of mold compound; a plurality of wire bonds that selectively establishes electrical between the semiconductor die, the set of terminal structures, and the set of redistribution structures; and hardened mold compound that encapsulates the semiconductor die, the set of terminal structures, the set of redistribution structures, and the plurality of wire bonds, wherein the bottom surface of each redistribution structure is vertically offset away from the back side of the continuous sheet of mold compound. The semiconductor die package also includes a die fixing structure as set forth above. Moreover, aspects of the set of terminal pads, the set of redistribution structures, the dielectric structure, the plurality of wire bonds, and the mold compound can be analogous or identical to that set forth above. The semiconductor die package can be a Quad Flat No Lead (QFN) package.

In accordance with an aspect of the present disclosure, a process for fabricating packaged semiconductor die by way of a lead carrier includes: providing a temporary support layer having a top side on which semiconductor die packages are to be fabricated at corresponding package sites, each package site comprising a predetermined fractional area of the temporary support layer on the top side thereof; providing a preform structure on the top side of the temporary support layer, the preform having: a first preform layer having openings formed therein through which the top side of the temporary support layer is exposed, and which define at each package site a first predetermined pattern; and a second preform layer disposed above the first preform layer, which includes a set of cavities formed therein that define at each package site a second predetermined pattern; disposing a paste carrying a sinterable metal in the openings of the first preform layer and the cavities of the second preform layer; and sintering the paste to fabricate at each package site each of: a set of terminal structures corresponding to the first predetermined pattern, wherein each terminal structure has a top side, an opposing back side adhered to the temporary support layer, and a height between its top and back sides, and a set of current path redistribution structures corresponding to the second predetermined pattern, wherein each redistribution structure comprises an elongate wiring structure having a width, a first end, a distinct second end, a top surface, a bottom surface, and a thickness between its top and bottom surfaces, wherein the bottom surface of each redistribution structures is offset away from the top side the temporary support layer, and wherein within the set of redistribution structures any given redistribution structures comprises one of (a) a pre-linked redistribution structure that as-fabricated is electrically pre-coupled to a predetermined terminal structure, or (b) an initially-unlinked redistribution structure that as-fabricated is electrically isolated from each terminal structure and the temporary support layer. The set of redistribution structures can include one or more pre-linked redistribution structures and/or one or more initially-unlinked redistribution structures.

The process further includes: providing a dielectric structure disposed between the top surface of the temporary support layer and the bottom surface of each redistribution structure; at each package site, disposing a semiconductor die in a central region of the package site such that each terminal structure of the package site are peripheral to the semiconductor die; at each package site, forming a plurality of wire bonds that selectively establishes electrical couplings between the semiconductor die, the set of terminal structures, and the set of redistribution structures; forming a continuous sheet of molded package sites by applying a mold compound across the package sites such that the semiconductor die, the set of terminal pads, the set of redistribution structures, and the plurality of wire bonds are encapsulated in the mold compound; peeling the temporary support layer away from the continuous sheet of molded package sites; and separating individual package sites within the continuous sheet of molded package sites from each other to thereby form individual packages that each contain a selected semiconductor die, the set of terminal structures, the set of redistribution structures, and the plurality of wire bonds, wherein each package includes a top side and an opposing bottom side at which the bottom sides of the set of terminal structures of the package are exposed to thereby form surface mount junctions of the package.

The plurality of wire bonds includes first wire bonds selectively formed between the semiconductor die and the set of redistribution structures, and second wire bonds selectively formed between the semiconductor die and the set of terminal structures. The set of redistribution structures can include at least one initially-unlinked redistribution structure, whereupon the plurality of wire bonds can further include third wire bonds selectively formed between the set of terminal structures and the at least one initially-unlinked redistribution structure.

### BRIEF DESCRIPTION OF THE DRAWINGS

FIG. 1 is an illustration of a conventional etched lead frame, used in the fabrication of QFN semiconductor packages.

FIG. 2 is an enlarged view of a portion of the lead frame of FIG. 1, showing a single package site or package assembly site of this lead frame.

FIG. 3 is an illustration of a lead carrier in accordance with an embodiment of the present disclosure, for the fabrication, assembly, or manufacture of a plurality of QFN type semiconductor packages thereon in accordance with an embodiment of the present disclosure.

FIG. 4A is an enlargement of an individual package assembly site corresponding to lead carrier in accordance with an embodiment of the present disclosure.

FIG. 4B is an enlargement of an individual package assembly site corresponding to lead carrier in accordance with another embodiment of the present disclosure.

FIGS. 5(a)-5(h) are cross sectional views illustrating portions of a representative process for fabricating a lead carrier in accordance with an embodiment of the present disclosure.

FIG. 6 shows details of a representative pre-linked redistribution structure in accordance with an embodiment of the present disclosure.

FIG. 7 illustrates an embodiment of a lead carrier in accordance with the present disclosure that includes a dielectric structure disposed below and possibly around vertically extending portions of redistribution structures of a package site or package formed therefrom.

FIG. 8 shows a representative embodiment of a lead carrier in accordance with the present disclosure in cross section form, after sintering and after the application of a dielectric structure to the lead carrier, and prior to the formation of wire bonds on the lead carrier.

FIG. 9 is a cross-sectional schematic illustration showing further aspects of a lead carrier manufacturing process in accordance with an embodiment of the present disclosure, in which a bi-layer preform structure is provided to fabricate redistribution structures on a lead carrier.

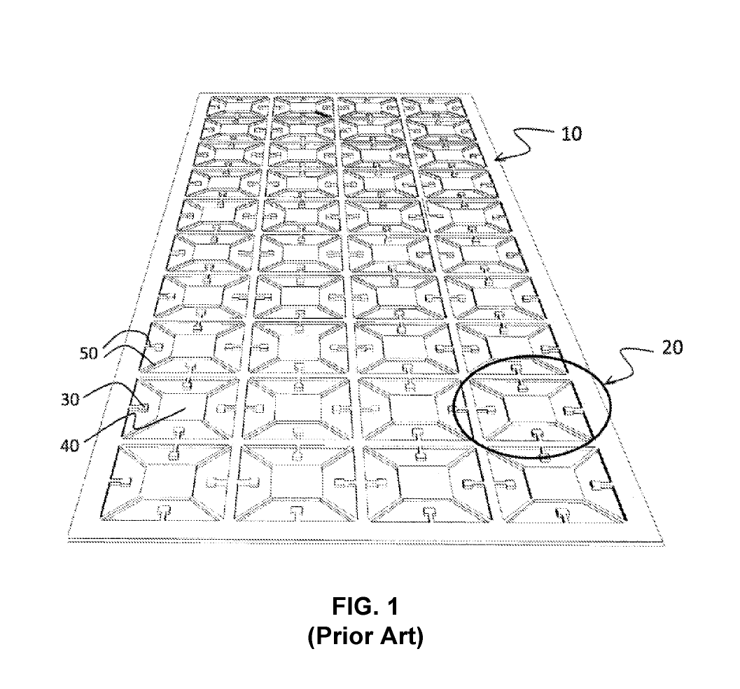

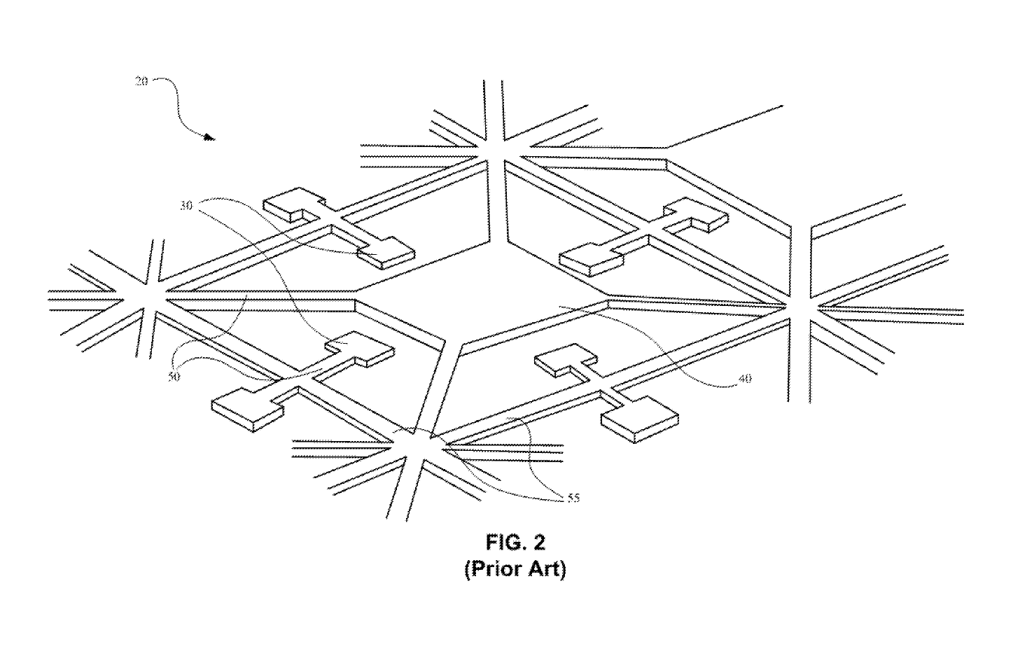

### DETAILED DESCRIPTION

Aspects of the present disclosure are described in detail hereafter with reference to the drawings, which illustrate particular representative embodiments in accordance with the present disclosure.

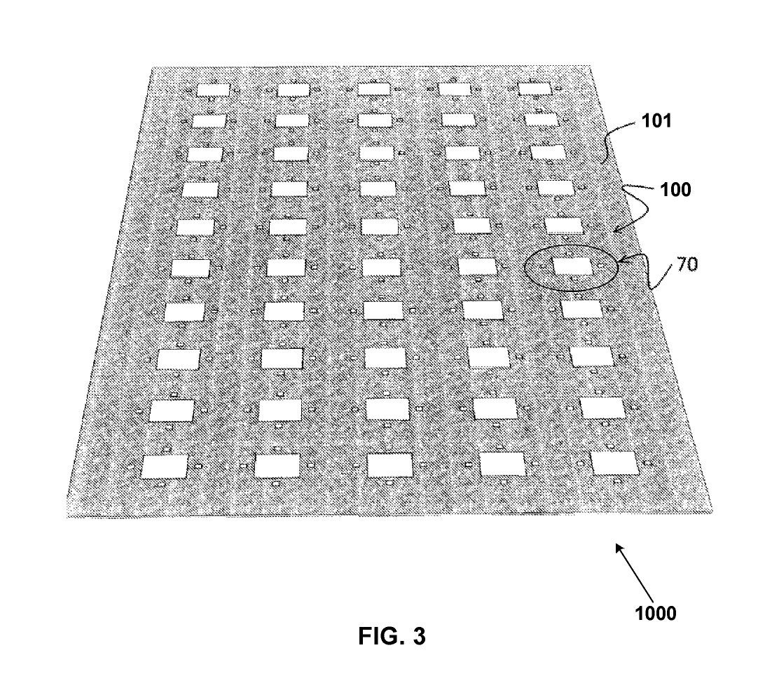

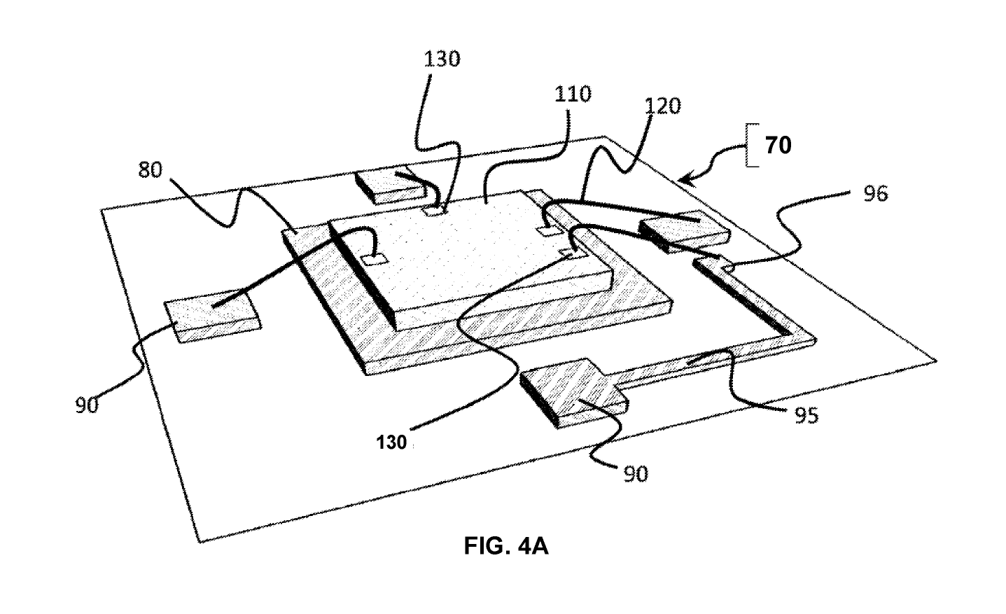

FIG. 3 illustrates a lead carrier 1000 in accordance with an embodiment of the present disclosure, which includes a temporary support layer, member, medium, or carrier 100 having a top side or surface 101 upon which are arrayed a plurality of semiconductor package sites 70. FIG. 4A is an enlarged or close up view showing a representative individual package site 70 in accordance with an embodiment of the present disclosure, which includes a set of die fixing structures 80, each of which is configured for receiving a semiconductor die, integrated circuit chip, or other type of semiconductor or microelectronic device (e.g., a microelectromechanical (MEMS) device) 110; an array of electrically conductive terminal structures 90 associated with the die fixing structure(s) 80; and at least one electrically conductive first or pre-linked redistribution structure 95. Such a redistribution structure 95 includes a first or proximal portion or end that is electrically pre-coupled or pre-connected to a corresponding terminal structure 90, and which projects or extends away from this terminal structure 90; a second or distal portion or end that is disposed away from this terminal structure 90, and which as-fabricated is initially electrically not coupled or connected to any particular wire bond pad 130 disposed on an upper surface of a semiconductor die 110; and an elongate wiring portion that extends between its proximal and distal ends. Thus, in embodiments such as that depicted in FIG. 4A, at least one pre-linked redistribution structure 95 corresponds to, is electrically pre-linked, coupled, or connected to, and projects or extends away from a particular terminal structure 90, for instance, a predetermined terminal structure 90 to which the proximal end of the pre-linked redistribution structure 95 is electrically coupled or connected as a result of the manner in which this redistribution structure 95 and its corresponding terminal structure 90 were formed or integrally joined during a lead carrier manufacturing process. The distal end of the pre-linked redistribution structure 95 can be disposed remote from the terminal structure 90 to which the pre-linked redistribution structure corresponds, with respect to the overall dimensions of the package site 70. In some embodiments, one or more pre-linked redistribution structures 95 include a corresponding remote terminal structure 96, for instance at the distal end of the pre-linked redistribution structure 95.

In addition to the foregoing, the pre-linked redistribution structure 95 includes top and bottom surfaces that extend along its length. The top surface of the pre-linked redistribution structure 95 can be parallel to or coplanar with the top side of its corresponding terminal structure 90. The bottom surface of the pre-linked redistribution structure 95 is disposed above the top side 101 of the temporary support layer, and hence above the bottom side of its corresponding terminal structure 90 (e.g., and above the bottom sides of each terminal structure 90 at the package site 70). The pre-linked terminal structure 95 can thus be defined as an elevated or partial thickness electrically conductive structure or element relative to its corresponding terminal structure 90, which does not directly contact the top side 101 of the temporary support layer 100 in contrast to its corresponding terminal structure 90.

Wire bonds 120 can be systematically and selectively formed between input/output junctions or wire bond pads 130 disposed on an upper surface of the semiconductor die 110 and (a) the terminal structures 90 and (b) the remote terminal structures(s) 96 of the package site 70, in a manner readily understood by individuals having ordinary skill in the art.

For purpose of simplicity and to aid understanding, the representative embodiment shown in FIGS. 4A is significantly simplified over a typical embodiment, in that the package site 70 is shown as including only four terminal pads 90 surrounding each die fixing structure 80; the package site 70 includes a single pre-linked redistribution structure 95 corresponding to one of the terminal structures 90; and the upper surface of the integrated circuit chip 110 includes only four wire bond pads 130, three of which are directly wire bonded to terminal structures 90 of the package site 70, and one of which is directly wire bonded to the remote terminal structure 96 of the pre-linked redistribution structure 95.

Individuals having ordinary skill in the relevant art will understand that in a typical embodiment, the integrated circuit chip 110 includes at least one and potentially hundreds of wire bond pads 130. Correspondingly, at least one and potentially hundreds of terminal structures 90 are present surrounding the die fixing structure(s) 80; and pre-linked redistribution structures 95 can also be present in numbers of one or more depending upon embodiment and situational details. The terminal structures 90 are typically present in multiple rows (e.g., two or more rows), including an innermost row closest to the die fixing structure(s) 80, an outermost row most distant from the die fixing structure(s) 80, and potentially one or multiple intermediate rows between the innermost row and the outermost row of terminal structures 90. The pre-linked redistribution structures 95 and their corresponding remote terminal structures 96 can be routed or disposed within, between, and/or around particular terminal structures 90. Moreover, some or all terminal structures 90, pre-linked redistribution structures 95, and/or remote terminal structures 96 can be smaller or larger relative to each other and/or the die fixing structure 90 depicted in the simplified representative embodiment of FIG. 4A.

FIG. 4B is an enlarged or close up view showing a representative individual package site 70 in accordance with another embodiment of the present disclosure. In embodiments such as that depicted in FIG. 4B, the package site 70 includes one or more die fixing structures 80 configured for receiving a semiconductor die 110; an array of electrically conductive terminal structures 90 associated with the die fixing structure(s) 80; and at least one electrically conductive second or initially-unlinked redistribution structure 97 associated with the set of die fixing structures 80. For purpose of simplicity and to aid understanding, the embodiment shown in FIG. 4B is significantly simplified relative to a typical embodiment, in a manner analogous to that for FIG. 4A.

The initially-unlinked redistribution structure 97 includes a first end disposed at a first (x, y) location of the package site 70; a second end disposed at a distinct second (x, y) location of the package site 70, which can be remote from the first (x, y) location relative to the package site's dimensions; and an elongate wiring structure extending between the first end and the second end of the initially-unlinked redistribution structure 97. The initially-unlinked terminal structure 97 further includes a top surface that is parallel to or coplanar with the top sides of the terminal structures 90; and a bottom surface that is disposed above the top side 101 of the temporary support layer 100 and hence above the bottom sides of the terminal structures 90.

Neither the first end of the initially-unlinked redistribution structure 97, the second end of the initially-unlinked redistribution structure 97, nor the elongate wiring structure therebetween is coupled or connected to any terminal structure 90 prior to a wire bonding procedure that is performed after the fabrication of the initially-unlinked redistribution structure 97 and the terminal structures 90 to selectively or selectably establish an electrical coupling or connection between a particular portion of the initially-unlinked redistribution structure 97 and a selected or selectable terminal structure 90. Thus, the initially-unlinked redistribution structure 97 can be defined as an elevated or partial thickness electrically conductive structure or element that as-fabricated is not electrically coupled or connected to the package site's terminal structures 90 or the temporary support layer 100 (e.g., as-fabricated, the initially-unlinked redistribution structure 97 can be defined as an electrically floating structure or element).

A wire bond 120 can also be formed between a selected wire bond pad 130 disposed on the upper surface of the semiconductor die 110 and a particular portion of the initially-unlinked redistribution structure 97 to thereby electrically couple, link, or connect this redistribution structure 97 to the semiconductor die 110, in a manner individuals having ordinary skill in the art will readily understand. Similarly, a wire bond 120 can also be selectively formed between a selected terminal structure 90 and another portion of the initially-unlinked redistribution structure 97 to thereby electrically couple, link, or connect this redistribution structure 97 to the selected terminal structure 90.

As indicated in FIG. 4B, a given initially-unlinked redistribution structure 97 can include one or more remote terminal structures 96 thereon or therealong, in a manner analogous to that for the pre-linked redistribution structure 95 described above. For instance, an initially-unlinked redistribution structure 97 can include a remote terminal structure 96 at its first end, its second end, and/or one or more locations along the length of the elongate wiring structure that extends between its first end and second end ***please confirm***. Thus, a first wire bond 120 can be formed between a particular wire bond pad 130 of the semiconductor die and a selected (e.g., first) remote terminal structure 96 of a given initially-unlinked redistribution structure 97 to thereby electrically couple, link, or connect this redistribution structure 97 to the semiconductor die 110; and a second wire bond 120 can be formed between a selected terminal structure 90 and another (e.g., second) remote terminal structure 96 of this redistribution structure 97 to thereby electrically couple, link, or connect this redistribution structure 97 to the selected terminal structure 90.

In the description that follows, the die fixing structures 80, the terminal structures 90, the pre-linked and/or initially-unlinked redistribution structures 95, 97, and the remote terminal structures 96 corresponding thereto can be collectively referred to as interconnect structures. In various embodiments, the interconnect structures can include a metal or metal alloy (e.g., a single metal or metal alloy) such as silver that is compatible with both gold thermosonic wire bonding and SMT soldering processes.

The interconnect structures can be formed in association with the application or deposition of metal powder mixed with or distributed or dispersed in a suspension medium on the temporary support layer 100 in a first controlled or precisely controlled spatial configuration, and then heating the temporary support layer 100 carrying the metal powder in the suspension medium to a temperature sufficient to cause (a) the suspension medium to decompose and disperse, and (b) the metal powder to be sintered into structures having a high density mass in a second controlled or highly controlled configuration that is related or which corresponds to the configuration or profile that the metal powder in suspension medium exhibited or occupied when disposed on the temporary support layer 100.

After sintering, a molding process is performed during which an epoxy mold compound is applied or distributed across the entire lead carrier 1000 such that at each package site 70 thereof the semiconductor die(s) 110, the die fixing structure(s) 80, the terminal structures 90, the redistribution structure(s) 95, 97, remote terminal structure(s) 96, and wire bonds 120 are encased, encapsulated, or embedded in the epoxy mold compound. As a result of the molding process, a continuous sheet, strip, or array of molded package sites 70 exists on and is supported by the temporary support layer 100. Each molded package site 70 includes at least one semiconductor die 110 plus associated interconnect structures and wire bonds 110 embedded in the mold compound 70. In the sheet, strip, or array of molded package sites, each package site 70 is structurally connected to an adjacent or adjoining package site 70 by way of the hardened mold compound. Thus, in a molded sheet that includes at least three molded package sites 70, each molded package site 70 is structurally connected to a plurality of nearest neighbour molded package sites 70 by the hardened mold compound 70.

After the mold compound has hardened, the temporary support layer 100 can be peeled away from the sheet of molded package sites 70, yielding a continuous stand-alone or unsupported sheet, strip, or array of molded package sites 70. As a result of the aforementioned sintering process, the die fixing structures 80 and terminal structures 90 are adhered well enough to the temporary support layer 100 to preclude them from being dislodged or damaged during package fabrication or assembly, but still have low enough adhesion to the temporary support layer 100 such that they can cleanly peel away from the temporary support layer 100 while remaining in their intended positions in the unsupported strip of molded package sites 70.

After the temporary support layer 100 has been peeled away, the surfaces of the die fixing structures 80 and terminal structures 90 opposite to the top surfaces of the semiconductor dies 110 and the top surfaces of the terminal structures 90 to which wire bonds 120 are fixed remain exposed on one surface of the sheet or strip of unsupported molded package sites 70, which can be defined as the back or bottom surface of this unsupported molded sheet or strip. Furthermore, in the supported as well as the unsupported sheet or strip of molded package sites 70, the interconnect structures, i.e., the die fixing structures 80, terminal structures 90, redistribution structures 95, 97 and remote terminal structures 96, of any given package site 70 are completely electrically isolated from the components of any other package site 70.

The unsupported strip of molded package sites 70 can be singulated (e.g., by way of a cutting or sawing process) to yield individual packages corresponding to each package site 70, in a manner readily understood by individuals having ordinary skill in the art in view of the description herein.

At each package site 70, the addition of a semiconductor die 110 secured, mounted, or affixed to a die fixing structure 80, plus the selective establishment of wire bonds 120 between the wire bond pads 130 of the semiconductor die 100 and terminal structures 90 and remote terminal structures 96 arrayed around the die fixing structure 80, completes the formation of electrical couplings or connections of the semiconductor die 110 to the interconnect structures. An important difference between a package produced on a conventional lead frame 10 and a package produced on a lead carrier 1000 in accordance with an embodiment of the present disclosure is the ability to position a wire bond 120 at a receiving remote terminal structure 96 remote from the terminal structure 90 to which the remote terminal structure 96 is electrically coupled or connected by way of a redistribution structure 95, 97, thus allowing for optimum length and alignment of wire bonds 120.

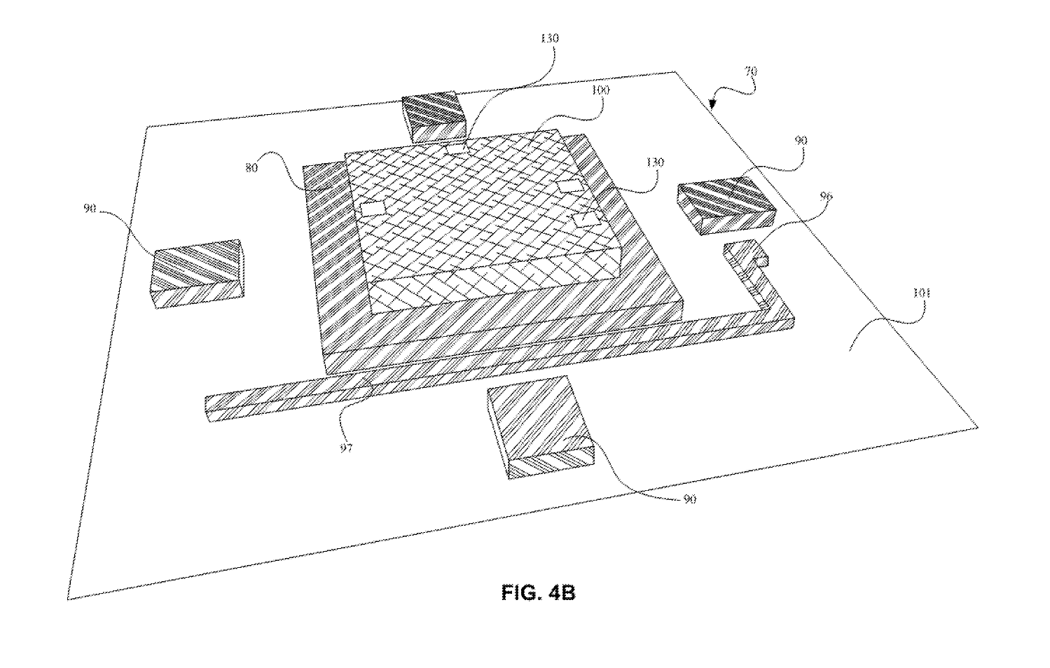

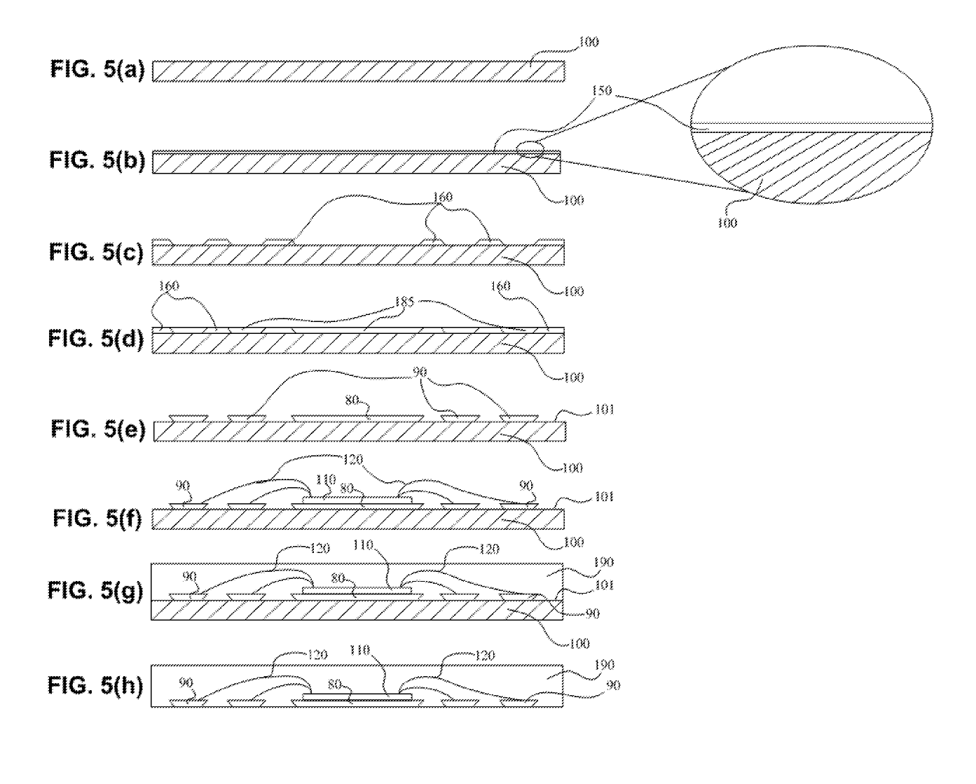

FIGS. 5(a)-(h) illustrate portions of a representative manufacturing process 1100 for a lead carrier 1000 in accordance with an embodiment of the present disclosure. It should be noted that while FIGS. 5(a)-(h) do not illustrate the development or fabrication of a redistribution structure 95, 97 or a corresponding remote terminal structure 96, the fabrication of such structures 95, 96, 97 is described in detail below with reference to FIGS. 6-9.

A lead frame manufacturing process 1100 in accordance with an embodiment of the present disclosure includes each of the following process portions or sub-processes:
FIG. 5(a): Providing a temporary support layer 100;
FIG. 5(b): Possibly or typically modifying the surface of the temporary support layer 100 to form an interface layer or interface 150 for controlling the adhesion of subsequent structures, elements, or layers to the temporary support layer 100;
FIG. 5(c): Providing or applying a temporary preform structure 160 on the temporary support layer 100, where the temporary preform structure 160 has a predetermined pattern that is the negative of a desired or intended pattern of terminal structures 90 on the temporary support layer 100 at each package site 70. Such a pattern includes open areas or openings that expose the interface 150 where the die fixing structures 80 and terminal structures 90 will be formed;
FIG. 5(d): Filling the open areas of the temporary preform structure 160 where the die fixing structures 80 and terminal structures 90 will be formed with a sintered structure precursor 185, which includes a metal powder (e.g., silver powder) in a flowable medium;
FIG. 5(e): Heating or heat treating the entire structure formed thus far to a sufficiently high temperature to cause the temporary preform structure 160 to be removed or decompose, and the sintered structure precursor to sinter into high density masses having contours, borders, or edges that faithfully reproduce or match the shapes of contours, borders, or edges of the openings in the temporary preform structure 160, and which form the die fixing structures 80 and terminal structures 90 of each package site 70;
FIG. 5(f): At each package site 70, fixing a semiconductor die 110 to the die fixing structure 80 and attaching bond wires 120 between the bond pads 130 on the semiconductor die 110 and particular terminal structures 90 arrayed around the die fixing structure 80;
FIG. 5(g): Encapsulating all of the components arrayed on the temporary support layer 100 with a mold compound or resin 190 to form a continuous supported sheet of molded package sites 70 having semiconductor die 110, terminal structures 90, and wire bonds 120 encased therein;
FIG. 5(h): Removing the temporary support layer 100 from the continuous supported sheet of molded package sites 70 by peeling the temporary support layer 100 away from this sheet to thereby yield a continuous unsupported or stand-alone sheet of molded package sites 70 having semiconductor die 110, terminal structures 90, and wire bonds 120 encased therein.

After the peeling process of FIG. 5(h), the semiconductor dies 110 corresponding to the package sites 70 of the continuous unsupported sheet of molded package sites 70 can be tested at high speed while still in the stand-alone sheet of molded package sites 70 before being singulated by sawing the sheet along predetermined borders between each of the package sites 70.

As indicated above, a lead frame manufacturing process 1100 in accordance with an embodiment of the present disclosure can include additional process portions in which one or more types of redistribution structures 95, 97 and corresponding remote terminal structures 96 can be formed at particular, selected, or customized locations within one or more package sites 70 (e.g., each package site 70).

FIG. 6 shows details of a representative pre-linked terminal structure 90 having a corresponding redistribution structure 95 electrically connected thereto, and which extends away therefrom in accordance with an embodiment of the present disclosure. Within each package site 70 or package, the terminal structures 90, the backs or bottom surfaces of which incorporate or form the surface mount interfaces of the package site 70 package, are organized in a predetermined pattern to coordinate with solder pads on a printed circuit (PC) board, in a manner readily understood by individuals having ordinary skill in the relevant art. Since it is desirable in some instances to relocate particular wire bonds 120 away from what would conventionally be their corresponding surface mount interfaces provided by certain terminal structures 90, several embodiments in accordance with the present disclosure provide redistribution structures 95, 97 that include or form elongate wiring structures that are disposed in relation to terminal structures 90 at specific target package site (x, y) locations, and which can be routed, for instance, adjacent to, between, and/or around specific terminal structures 90 (e.g., in a predetermined, selected, or customized routing pattern, which can include straight and/or curved segments), and if desirable, redirected or routed along one or more directions, such as in the manner illustrated in FIG. 6.

In some embodiments, it is desirable to enlarge a particular portion of a redistribution structure 95, 97 such as an end portion or end thereof to thereby form a remote terminal structure 96 corresponding to the redistribution structure 95, 97 which provides an enlarged wire bonding area relative to the width of the redistribution structure 95, for instance, in a manner illustrated in FIG. 6. The inclusion of the remote terminal structure 96 can optimize the redistribution structure 95, 97 for an intended purpose, such as stabilizing the end portion or end (e.g., the distal end, in the case of a pre-linked redistribution structure 95) of the redistribution structure 95, 97 for wire bonding. The redistribution structure 95, 97 can be substantially narrower (e.g., 25%-75% narrower depending upon embodiment details) than a terminal structure 90 to which it is electrically coupled or connected or from which it extends, thereby allowing the redistribution structure 95, 97 to be routed between other electrically conductive structures such as other terminal structures 90 and/or other redistribution structures 95, 97 within the package site 70.

A redistribution structure 95, 97 is also smaller or shorter than a terminal structure 90 (e.g., a terminal structure 90 to which it is electrically coupled or connected) in terms of its overall vertical extent, height, depth, or thickness, extending downwardly from the surface of the terminal structure 90 that is furthest from the temporary support layer 100, i.e., the top surface of the terminal structure 90, toward but not contacting the temporary support layer 100. Therefore, a bottom surface of the redistribution structure 95, 97 is vertically offset or separated from the top side 101 of the temporary support layer 100 and hence the surface mount interface of the terminal structure 90 to which the redistribution structure 95, 97 is electrically coupled or connected. Consequently, during the molding process, mold compound will fill the space between the bottom surface of the redistribution structure 95, 97 and the top side 101 of the temporary support layer 100, such that after the continuous sheet of molded package sites 70 and the temporary support layer 100 are separated from each other by way of peeling, the surface mount interfaces of the terminal structures 90 remain visible from the bottom of the unsupported continuous molded sheet of package sites 70, but the redistribution structures 95, 97 are not visible.

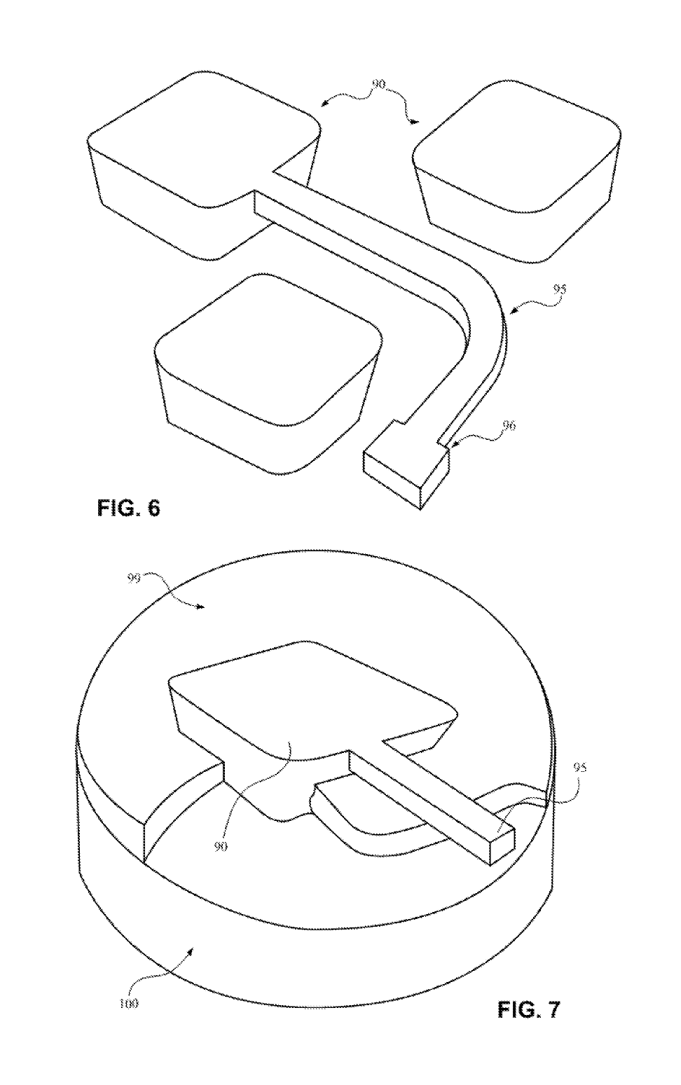

FIG. 7 illustrates an embodiment in accordance with the present disclosure that includes a dielectric structure 99 distributed or dispersed over the surface of the temporary support layer 100 in such a way as to cover the entire surface of the package site 70 of FIG. 3, except for those locations where the terminal structures 90 are attached to the temporary support layer 100, where the dielectric material or structure 99 fills the depth of the vertical gap or spacing between the (a) bottom surface of the redistribution structures 95 and the top side 101 of the temporary support layer 100, and correspondingly (b) the surface mount interfaces of the terminal structures 90, thus providing support and stabilization for the redistribution structures 95. While FIG. 7 illustrates a pre-linked redistribution structure 95, individuals having ordinary skill in the art will understand that the concepts illustrated in FIG. 7 equally apply to initially-unlinked redistribution structures 97.

The dielectric structure 99 typically includes or is formed of a granular material such as SiO₂ or Al₂O₃ containing compositions formulated to form sintered connections with adjoining granules at a temperature similar to the sintering temperature of the sintered structure precursor, such that individual grains of the granular material make contact with adjacent grains thereof over a small percentage of their total surface area, the result being a dielectric structure 99 with between, e.g., 25% and 90% open space volume therein. During the molding operation, resin from the mold compound can flow into portions of the open space volume of the dielectric structure 99, creating a robust bond between the mold compound and the dielectric structure 99, and creating a more robust dielectric layer or material overall that can have properties similar to the mold compound.

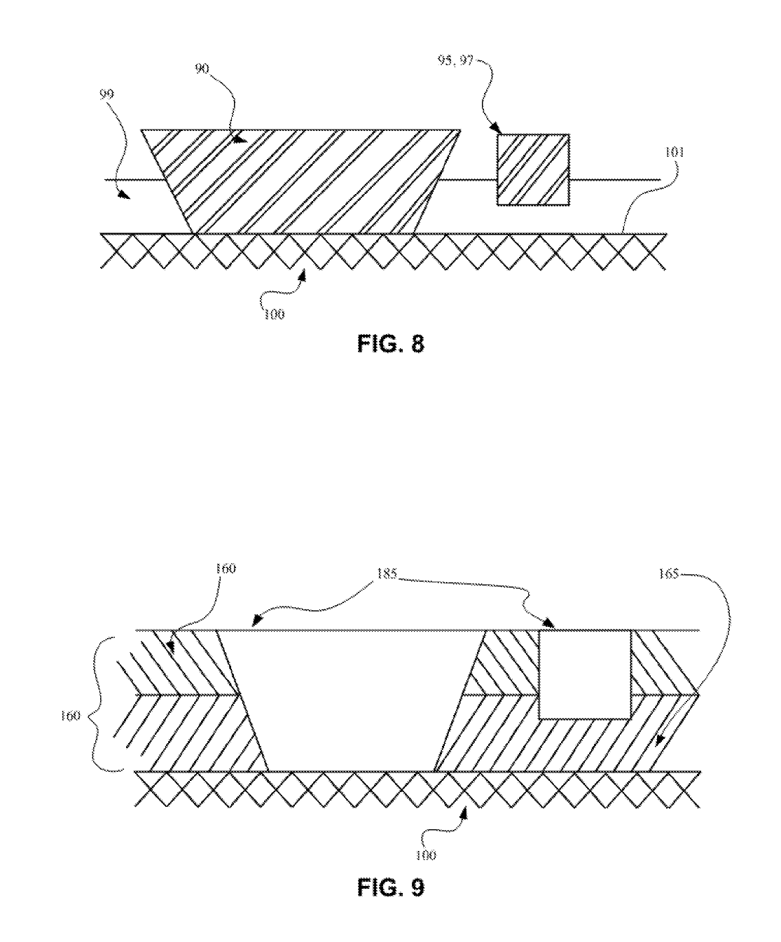

FIG. 8 shows a representative embodiment of a lead carrier 1000 in accordance with the present disclosure in cross section form, after sintering and after the application of the dielectric structure 99 to the lead carrier 1000, and prior to the formation of wire bonds 120 on the lead carrier 1000. In such an embodiment, the dielectric structure 99 is thicker or deeper than the vertical gap, spacing, or depth between the bottom of the redistribution structures 95, 97 and the top side 101 of the temporary support layer 100, and hence portions of the dielectric structure 99 surround at least a fraction of the overall height, depth, or thickness of the redistribution structures 95, 97. While FIG. 8 illustrates the dielectric structure 99 extending partially up the vertical extent, height, depth, or thickness of the redistribution structures 95, 97, depending upon embodiment details the dielectric structure 99 can have any desired, intended, or selected thickness between the bottom surfaces of the redistribution structures 95, 97 and the top surfaces of the terminal structures 90 and correspondingly the top surfaces of the redistribution structures 95, 97.

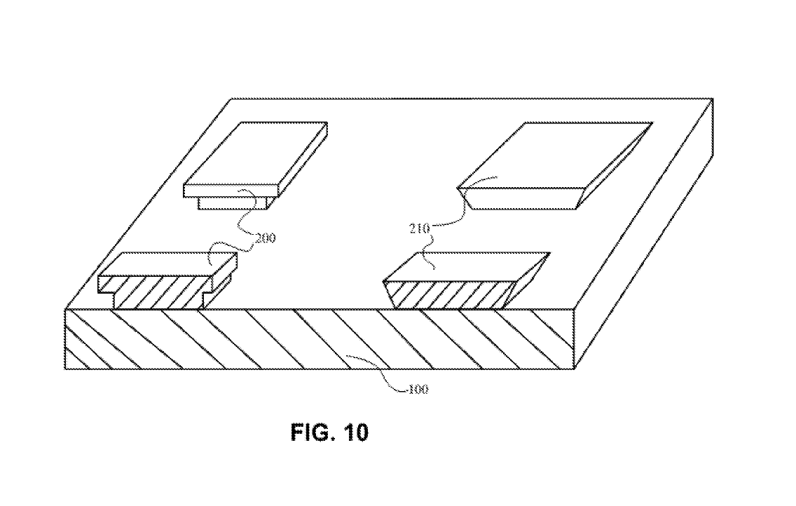

FIG. 9 is a cross-sectional schematic illustration showing further aspects of a lead carrier manufacturing process 1100 in accordance with an embodiment of the present disclosure, where the lead carrier 1000 is fabricated to carry or include redistribution structures 95, 97. In an embodiment, a multi-layer or bi-layer preform structure 162 is fabricated from two different preform components, namely, a first or fully sacrificial upper preform structure 160 and a second or composite lower preform structure 165. The lower preform structure 165 includes openings formed therein that will determine or control the final configuration of the lead carrier's terminal structures 90 (e.g., in accordance with a terminal structure formation or fabrication pattern), and the shapes of the peripheral borders or edges of the terminal structures 90 (which typically have an overhanging or undercut profile, as detailed below). In embodiments that include die fixing structures 80 formed of the same material as the terminal structures 90, the lower preform structure 165 also includes openings therein that will determine or control the final configuration of the lead carrier's die fixing structures 80 (which typically also have an overhanging or undercut profile, as detailed below). The upper preform structure 160 includes cavities or recesses formed therein that will determine or control the final configuration of redistribution structures 95, 97 (e.g., in accordance with a redistribution structure formation or fabrication pattern), and the shapes of the peripheral borders of edges of the redistribution structures 95, 97 (which are typically rectangular in profile, but which can have a trapezoidal or other type of profile).

After the multi-layer preform structure 162 is provided on the temporary support layer 100, the openings of the composite lower preform structure 165 and the cavities of the sacrificial upper preform structure 160 are filled with a sintered material precursor 185. The composite lower preform structure 165 is formed or constituted of granules of an inorganic material chosen for its ability to sinter in the same temperature range as the sintered material precursor 185, plus an organic matrix chosen to volatize and burn away cleanly in a temperature range between 300° C. and 600° C. The sacrificial upper preform structure 160 is formed or constituted of an organic material chosen to volatize and burn cleanly away in a temperature range between 300° C. and 600° C. The sacrificial upper preform structure 160 and the organic matrix of lower preform structure 165 can include or be formed of an epoxy or acrylic material. Upon processing to a sintering temperature, the organic components of the sacrificial upper preform means 160 and the composite lower preform means 165 will be removed by volatization at a temperature that is less the sintering temperature; and at the sintering temperature, the sintered material precursor will subsequently sinter and densify to form the die fixing structures 80, the terminal structures 90 and redistribution structures 95, 97 of the lead carrier 1000, while the composite lower preform structure 165 sinters and densities to form the lead carrier's dielectric structure 99.

After the formation of the die fixing structures 80, the terminal structures 90, and redistribution structures 95, 97 by way of the sintering process, semiconductor dies 110 can be fixed to the die fixing structures 80 and wire bonds 120 can be selectively formed to electrically connect each semiconductor die 110 to particular terminal structures 90 and redistribution structures 95, 97 (e.g., remote terminal structures 96 of the redistribution structures 95, 97), in a manner readily understood by individuals having ordinary skill in the art.

FIG. 10 shows representative cross-sectional shapes or edge profiles for the die fixing structures 80 and the terminal structures 90 in accordance with particular embodiments of the present disclosure, where such shapes or edge profiles mechanically key such package components into the mold compound or resin encapsulant. More particularly, such shapes or edge profiles include or establish overhangs or undercuts that structurally engage with hardened mold compound to resist or prevent such package components from being vertically separated from the package in which they reside. Depending upon embodiment details, package components 200 can have a cross-sectional shape or edge profile corresponding to a “T” structure or mushroom structure; and/or package components 210 can have an inverted frustum cross-sectional shape. In both cases, the largest surface of the package components 200, 210 is on the surface thereof that is opposite to and does not make contact with the temporary support layer 100.

Certain aspects of present disclosure are somewhat similar to the electroplated lead carrier described in U.S. Pat. No. 7,187,072 by Fukutomi et al, in that the package components are arrayed on a sacrificial carrier. However, in contrast to Fukutomi et al., instead of forming the package components by electroplating, the package components are created by way of the deposition of a sinterable paste onto a temporary support layer 100, where the paste includes a metal powder and a volatile or combustible fluid. The temporary support layer 100 and the precision deposited paste are heated to a temperature sufficient to sinter the powdered metal within the paste to a high density to thereby form particular types of package components in accordance with corresponding predetermined patterns. During such thermal processing, the sintered metal components are adhered to the temporary support layer 100 with sufficient tenacity to prevent subsequent displacement or damage thereto during the package assembly process, but with sufficiently weak bonding to allow the temporary support layer 100 to be cleanly peeled away from the continuous sheet of molded package sites 70, with all of the components securely embedded in the mold compound of the continuous sheet of molded package sites 70.

The temporary support layer 100 includes or is formed of a material that is stable at the temperature or temperature range necessary to sinter the metal powder used to form the package components. In one embodiment, the temporary support layer 100 includes or is formed of a ferrous alloy containing from 15% to 25% of chromium and 0% to 25% nickel. Such ferrous alloys are well suited for package components that include or which are formed of silver or alloys of silver. Alloys of gold are also well suited to a ferrous alloy temporary support layer 100, but special care must be exercised to avoid the formation of a gold/iron alloy which has several undesirable characteristics. Ferrous alloys are cost effective and possess thermal and chemical properties that are well suited to many materials that can be used as the basis for the package components, but other metals and metal alloys, ceramics, and even composite materials are practical for inclusion in or formation of the temporary support layer 100 when paired with the proper material(s) for the package components formed thereon.

In an embodiment, the package components include or are formed or of silver or a silver alloy containing from 2% to 25% palladium, gold, or other platinum group metal. The silver or silver alloy is provided as a powder with average particle sizes in the range of 1 micron to 25 microns, and is compounded into a paste by combining with a fluid. The result is a suspension with a consistency similar to toothpaste or peanut butter. The fluid can be based on water or a hydrocarbon, and also contains additives that modify the rheology of the suspension to optimize the deposition process and facilitate a temporary hardening to provide handling robustness prior to the sintering process.

Because the mold compound used to encapsulate all of the package components is formulated to release cleanly from the underlying temporary support layer 100, e.g., which is typically formed of metal, it's adhesion to the metal package components is also reduced. This limited adhesion between metal package components and the mold compound dictates that the package components be mechanically keyed into the mold compound to resist pullout of the package components from the hardened mold compound during the process of peeling the strip of molded packages from the temporary support layer 100.

In an embodiment, a process for depositing the metal filled paste that will form the package components is by way of a printing process such as screen printing or stencil printing. A problem with printing the structures directly is that final form of the components tends to be frusta having their larger area or larger diameter base attached to the temporary support layer 100 (i.e., the larger lower base resides on the temporary support layer 100), and their opposing smaller area or smaller diameter base furthest removed from the temporary support layer 100 (i.e., the opposing smaller upper base is disposed away from the support member 100); which is the opposite of a structure that would be mechanically keyed into the mold compound.

Thus, various embodiments of the present disclosure utilize a layer of sacrificial material deposited on the temporary support layer 100 in a pattern that is the negative of the desired pattern of the package components. This sacrificial layer is essentially an array of openings, apertures, or holes that will be filled with the metal paste to form the package components. The required frusta, with their smaller area or smaller diameter bases in contact with the temporary support layer 100, are easily created by printing the negative shapes of the package components in the sacrificial layer and filling the negative shapes with the metal paste.

Alternatively, the sacrificial layer can be formed to allow the creation of package components having a cross section that is shaped like that of a mushroom or similar object.

In another embodiment, creating a sacrificial layer having the required shape for mechanically locking the package components to the mold compound involves utilizing liquid photoresist, such as SU8 photoresist. The photoresist is deposited on the temporary support layer 100 by a conventional technique such as spin coating or curtain coating, then imaged and developed using processes common to the electronics industry. A mushroom or similar type of shape can be created in the photoresist by imaging and developing a first layer of photoresist with holes having a desired size corresponding to the stem of the mushroom shape, and then coating the first layer of photoresist with a second layer of photoresist and imaging and developing the second layer with holes having he desired size corresponding to the mushroom caps. The second layer pattern of caps is aligned so that all of the caps are concentric with their respective stems.

The liquid photoresist can also form the desired frustum shape by imaging the photoresist with a diffuse light source. Such exposure will cause photoresist under the opaque portions of the photo mask to be exposed such that the developed photoresist will slope from where the edge of the opaque portions of the photo mask contacted the photoresist to the point where the photoresist contacts the temporary support layer 100, inside the projection of the photo mask on the temporary support layer 100 by an amount determined by that maximum angle of the incident light relative to a ray perpendicular to the photoresist surface. Negative acting dry film photoresists such as those supplied by Dupont or Rohm and Haas can also be used to produce photoresist based frustum shapes in both manners described above.

Control of the adhesion of the metal package components to the temporary support layer 100 is critical. In one embodiment, the temporary support layer 100 includes or is formed of an alloy of iron and chromium, commonly referred to as stainless steel, and the package components include or are formed of sintered silver provided by way of silver paste. If such a structure is heated in air to a temperature that will sinter the silver to a high density, with the silver paste directly in contact with the temporary support layer 100, the silver will form a metallurgical bond with the iron alloy and be much more tenaciously adhered to the temporary support layer 100 than desired. To prevent the silver from welding itself to the temporary support layer 100, it is necessary to form an interface layer between the temporary support layer 100 and the silver. Since the silver sinters to the appropriate density only at temperatures above about 850° C., the interface layer cannot be an organic material.

One advantage of using an iron/chromium alloy in or as the temporary support layer 100 is that chromium forms an oxide layer almost as soon as it is exposed to oxygen. While this oxide layer is not sufficient to preclude welding the silver to stainless steel at temperatures sufficient to sinter the silver, that oxide layer can be enhanced by thermal treatment in an oxidizing atmosphere having a temperature between 850° C. and 900° C.

The description herein is provided to reveal particular representative embodiments in accordance with the present disclosure. It will be apparent that various modifications can be made to the embodiments described herein without departing from the scope of the present disclosure, or the claims included herewith.

1. A lead carrier for assembling packaged semiconductor die encapsulated in a mold compound, the lead carrier comprising:
a continuous sheet of mold compound having a top side and an opposing back side, the continuous sheet of mold compound comprising an array of package sites, each package site corresponding to a semiconductor die package, each package site comprising:
a semiconductor die having a top side and an opposing back side, and which includes at least one wire bond pad on its top side;
a set of terminal structures, each terminal structure formed of a sintered material and having a top side, an opposing back side that is exposed at the back side of the continuous sheet of mold compound, and a height between its top and back sides;
a set of electrical current path redistribution structures, each redistribution structure comprising an elongate wiring structure formed of the sintered material and having a first end, a second end distinct from the first end, a top surface, an opposing bottom surface, a width, and a thickness between its top and bottom surfaces, wherein within the set of redistribution structures any given redistribution structure as-fabricated is either (a) a pre-linked redistribution structure that is electrically pre-coupled to a predetermined terminal structure, or (b) an initially-unlinked redistribution structure that is electrically isolated from each terminal structure;
a dielectric structure disposed between the bottom surface of each redistribution structure and the back side of the continuous sheet of mold compound;
a plurality of wire bonds that selectively establishes electrical couplings between the semiconductor die, the set of terminal structures, and the set of redistribution structures; and
hardened mold compound that encapsulates the semiconductor die, the set of terminal structures, the set of redistribution structures, and the plurality of wire bonds,
wherein the bottom surface of each redistribution structure is offset away from the back side toward the top side of the continuous sheet of mold compound.

2. The lead carrier of claim 1, wherein at least one redistribution structure integrally includes a remote terminal structure having has a width that is greater than the width of the elongate wiring structure.

3. The lead carrier of claim 2, wherein the at least one redistribution structure integrally includes a plurality of remote terminal structures.

4. The lead carrier of claim 1, wherein at each package site, the top surface of each redistribution structure is parallel with the top side of each terminal structure, wherein the bottom surface of each redistribution structure is not exposed at the back side of the continuous sheet of mold material, and wherein the back side of each terminal structure defines a surface mount junction for the semiconductor die package corresponding to the package site.

5. The lead carrier of claim 1, wherein the plurality of wire bonds comprises first wire bonds selectively formed between the semiconductor die and the set of redistribution structures, and second wire bonds selectively formed between the semiconductor die and the set of terminal structures.

6. The lead carrier of claim 5, wherein the set of redistribution structures includes at least one initially-unlinked redistribution structure, and wherein the plurality of wire bonds further comprises third wire bonds selectively formed between the set of terminal structures and the at least one initially-unlinked redistribution structure.

7. The lead carrier of claim 1, wherein the set of redistribution structures comprises at least one pre-linked redistribution structure and at least one initially-unlinked redistribution structure.

8. The lead carrier of claim 1, wherein the dielectric structure comprises a granular material having void spaces therein occupied by the mold compound.

9. The lead carrier of claim 8, wherein the granular material comprises between 25%-90% void spaces therein prior to mold compound occupancy of the void spaces.

10. The lead carrier of claim 1, wherein at each package site, the dielectric structure vertically extends from the bottom of the package site up to a fraction of the thickness of each redistribution structure, below the top surface of each redistribution structure.

11. The lead carrier of claim 1, wherein each redistribution structure is routed along, between, and/or around peripheral portions of one or more terminal structures.

12. The lead carrier of claim 11, wherein each package site comprises up to hundreds of terminal structures, and wherein each package site comprises a plurality of redistribution structures routed between peripheral portions of terminal structures.

13. The lead carrier of claim 1, further comprising a temporary support layer having a top side that supports the bottom side of the continuous planar sheet of mold compound and the bottom side of each terminal structure, and which is peelably removable therefrom.

14. The lead carrier of claim 13, wherein each terminal structure has a peripheral border, and wherein the peripheral border of at least one terminal structure within the set of terminal structures includes an overhang region that causes an upper portion of the terminal structure to laterally extend beyond a lower portion of the terminal structure, and wherein the overhang region interlocks with the hardened mold compound to resist downward vertical displacement of the terminal structure from the hardened mold compound.

15. The lead carrier of claim 14, wherein at each package site a level of adhesion of each terminal structure to the top surface of the temporary support layer is less than a level of adhesion of the peripheral border of the terminal structure to the hardened mold compound.

16. The lead carrier of claim 1, wherein each package site further comprises a die fixing structure having a top side on which the back side of the semiconductor die resides, and a back side that is exposed at the back side of the continuous sheet of mold compound to define a surface mount junction of the package corresponding to the package site.

17. A semiconductor die package having a top side and an opposing back side, the semiconductor die package comprising:
a semiconductor die having a top side and an opposing back side, and which includes at least one wire bond pad on its top side;
a set of terminal structures, each terminal structure formed of a sintered material and having a top side, an opposing back side that is exposed at the back side of the continuous sheet of mold compound, and a height between its top and back sides;
a set of electrical current path redistribution structures, each redistribution structure comprising an elongate wiring structure formed of the sintered material and having a first end, a second end distinct from the first end, a top surface, an opposing bottom surface, and a thickness between its top and bottom surfaces, wherein within the set of redistribution structures, any given redistribution structure as-fabricated is either (a) a pre-linked redistribution structure that is electrically pre-coupled to a predetermined terminal structure, or (b) an initially-unlinked redistribution structure that is electrically isolated from each terminal structure;
a dielectric structure that occupies a lower portion of the package between the bottom surface of each of the at least one redistribution structures and the bottom of the continuous sheet of mold compound;
a plurality of wire bonds that selectively establishes electrical between the semiconductor die, the set of terminal structures, and the set of redistribution structures; and
hardened mold compound that encapsulates the semiconductor die, the set of terminal structures, the set of redistribution structures, and the plurality of wire bonds,
wherein the bottom surface of each redistribution structure is vertically offset away from the back side of the continuous sheet of mold compound.

18. The semiconductor die package of claim 17, wherein the plurality of wire bonds comprises first wire bonds selectively formed between the semiconductor die and the set of redistribution structures, and second wire bonds selectively formed between the semiconductor die and the set of terminal structures.

19. The semiconductor die package of claim 18, wherein the set of redistribution structures includes at least one initially-unlinked redistribution structure, and wherein the plurality of wire bonds further comprises third wire bonds selectively formed between the set of terminal structures and the at least one initially-unlinked redistribution structure.

20. The semiconductor die package claim 17, wherein the set of redistribution structures comprises at least one pre-linked redistribution structure and at least one initially-unlinked redistribution structure.

21. The semiconductor die package of claim 17, further comprising a die fixing structure having a top side on which the back side of the semiconductor die resides, and a back side that is exposed at the back side of the package to define a surface mount junction thereof

22. The semiconductor die package of claim 17, wherein each terminal structure has a peripheral border, and wherein the peripheral border of at least one terminal structure includes an overhang region that causes an upper portion of the terminal structure to laterally extend beyond a lower portion of the terminal structures, and wherein the overhang region interlocks with the mold compound to resist downward vertical displacement of the terminal structures from the mold compound.

23. The semiconductor die package of claim 16, wherein the semiconductor die package is a Quad Flat No Lead (QFN) package.

24. A method for fabricating packaged semiconductor die by way of a lead carrier, the method comprising:
providing a temporary support layer having a top side on which semiconductor die packages are to be fabricated at corresponding package sites, each package site comprising a predetermined fractional area of the temporary support layer on the top side thereof;
providing a preform structure on the top side of the temporary support layer, the preform comprising:
a first preform layer having openings formed therein through which the top side of the temporary support layer is exposed, and which define at each package site a first predetermined pattern; and
a second preform layer disposed above the first preform layer, which includes a set of cavities formed therein that define at each package site a second predetermined pattern;
disposing a paste carrying a sinterable metal in the openings of the first preform layer and the cavities of the second preform layer; and
sintering the paste to fabricate at each package site each of:
a set of terminal structures corresponding to the first predetermined pattern, wherein each terminal structure has a top side, an opposing back side adhered to the temporary support layer, and a height between its top and back sides, and
a set of current path redistribution structures corresponding to the second predetermined pattern, wherein each redistribution structure comprises an elongate wiring structure having a width, a first end, a distinct second end, a top surface, a bottom surface, and a thickness between its top and bottom surfaces, wherein the bottom surface of each redistribution structures is offset away from the top side the temporary support layer, and wherein within the set of redistribution structures any given redistribution structures comprises one of (a) a pre-linked redistribution structure that as-fabricated is electrically pre-coupled to a predetermined terminal structure, or (b) an initially-unlinked redistribution structure that as-fabricated is electrically isolated from each terminal structure and the temporary support layer.

25. The method of claim 24, further comprising:
providing a dielectric structure disposed between the top surface of the temporary support layer and the bottom surface of each redistribution structure;
at each package site, disposing a semiconductor die in a central region of the package site such that each terminal structure of the package site are peripheral to the semiconductor die;
at each package site, forming a plurality of wire bonds that selectively establishes electrical couplings between the semiconductor die, the set of terminal structures, and the set of redistribution structures;
forming a continuous sheet of molded package sites by applying a mold compound across the package sites such that the semiconductor die, the set of terminal pads, the set of redistribution structures, and the plurality of wire bonds are encapsulated in the mold compound;
peeling the temporary support layer away from the continuous sheet of molded package sites; and
separating individual package sites within the continuous sheet of molded package sites from each other to thereby form individual packages that each contain a selected semiconductor die, the set of terminal structures, the set of redistribution structures, and the plurality of wire bonds, wherein each package includes a top side and an opposing bottom side at which the bottom sides of the set of terminal structures of the package are exposed to thereby form surface mount junctions of the package.

26. The method of claim 25, wherein the plurality of wire bonds comprises first wire bonds selectively formed between the semiconductor die and the set of redistribution structures, and second wire bonds selectively formed between the semiconductor die and the set of terminal structures.

27. The method of claim 26, wherein the set of redistribution structures includes at least one initially-unlinked redistribution structure, and wherein the plurality of wire bonds further comprises third wire bonds selectively formed between the set of terminal structures and the at least one initially-unlinked redistribution structure.

28. The method of claim 24, wherein the set of redistribution structures comprises at least one pre-linked redistribution structure and at least one initially-unlinked redistribution structure.
